(19) United States
(12) Patent Application Publication
(10) Pub. No.: US 2026/0176753 A1
(43) Pub. Date: Jun. 25, 2026

(54) APPARATUS CLEANING METHOD AND SUBSTRATE TREATMENT APPARATUS FOR PERFORMING THE SAME

(71) Applicant: SAMSUNG ELECTRONICS CO., LTD., Suwon-si (KR)

(72) Inventors: Minseung CHA, Suwon-si (KR); Minsang Kim, Suwon-si (KR); Jinho Sung, Suwon-si (KR); Chulju Cho, Suwon-si (KR); Kwangje Choi, Suwon-si (KR)

(73) Assignee: SAMSUNG ELECTRONICS CO., LTD., Suwon-si (KR)

(21) Appl. No.: 19/265,351

(22) Filed: Jul. 10, 2025

(30) Foreign Application Priority Data
Dec. 19, 2024 (KR) 10-2024-0191788

(51) Int. Cl. C23C 16/44; C23C 16/52

(52) U.S. Cl. CPC C23C 16/4405; C23C 16/52

(57) ABSTRACT

Provided is An apparatus cleaning method and apparatus for performing same. The method includes: supplying a first cleaning gas to a target area of a substrate treatment apparatus, wherein the first cleaning gas is selected to react with a compound including Si—Cl bonds; and removing HCl gas from the target area after the supplying the first cleaning gas to the target area.

### CROSS-REFERENCE TO RELATED APPLICATION

This application is based on and claims priority to Korean Patent Application No. 10-2024-0191788, filed on Dec. 19, 2024, in the Korean Intellectual Property Office, the disclosure of which is incorporated by reference herein in its entirety.

### BACKGROUND

### 1. Field

The present disclosure relates to an apparatus cleaning method for cleaning a substrate treatment apparatus and a substrate treatment apparatus performing the same, and more particularly, to an apparatus cleaning method capable of removing Si—Cl bonding deposited inside a substrate treatment apparatus and a substrate treatment apparatus performing the same.

### 2. Description of Related Art

Generally, HCl gas, which is harmful to the human body, is formed in a deposition process in which DCS SiH₂Cl₂ gas is supplied to form a SiO₂ film on a substrate, such as a DCS MTO (DCS Middle Temperature Oxide) process. Therefore, a purge is performed inside a substrate treatment apparatus performing the process to prevent such HCl gas from leaking out or affecting an operator before managing a substrate treatment apparatus.

However, as described above, compounds including Si—Cl bonds are deposited in the substrate treatment apparatus where the deposition process for forming a SiO₂ film on the substrate by supplying DCS gas is performed, and the compounds including Si—Cl bonds may react with the purge gas to generate HCl gas.

Therefore, HCl gas may remain in the substrate treatment apparatus, even after the purge is performed.

### SUMMARY

Provided is an apparatus cleaning method capable of removing compounds including Si—Cl bonds deposited inside a substrate treatment apparatus, and a substrate treatment apparatus performing the same.

further provided is an apparatus cleaning method capable of increasing the removal efficiency of HCl gas inside a substrate treatment apparatus, and a substrate treatment apparatus performing the same.

According to an aspect of the disclosure, an apparatus cleaning method includes: supplying a first cleaning gas to a target area of a substrate treatment apparatus, wherein the first cleaning gas is selected to react with a compound including Si—Cl bonds; and removing HCl gas from the target area after the supplying the first cleaning gas to the target area.

According to an aspect of the disclosure, a substrate treatment apparatus includes: a substrate treatment chamber including a processing space configured to receive a substrate; a processing gas supply configured to supply a processing gas into the processing space; a first cleaning gas supply configured to supply, into the processing space, a first cleaning gas, wherein the first cleaning gas is selected to react with a compound including an Si—Cl bond and to generate HCl gas and a compound including an Si-bond that is more stable than the compound including the Si—Cl bond; a second cleaning gas supply configured to supply, into the processing space, a second cleaning gas that is selected to react with the HCl gas to generate a compound having a lower toxicity than HCl gas; memory storing instructions; and a controller including one or more processors configured to individually or collectively execute the instructions, wherein the instructions, when executed by the one or more processors individually or collectively, cause the substrate treatment apparatus to: control the first cleaning gas supply to supply the first cleaning gas into the processing space, and control the second cleaning gas supply to supply the second cleaning gas into the processing space.

According to an aspect of the disclosure, a substrate treatment apparatus includes: a substrate treatment chamber including a processing space configured to receive a substrate; a substrate waiting chamber including a waiting space configured to hold the substrate, wherein the waiting space is adjacent to the processing space and is connected to the processing space by an opening; a shutter configured to open and close the opening between the waiting space and the processing space; a substrate support configured to support the substrate and to move between the processing space and the waiting space through the opening; a processing gas supply configured to supply a processing gas into the processing space; a first cleaning gas supply configured to supply, into the processing space, a first cleaning gas, wherein the first cleaning gas is selected to react with a compound including an Si—Cl bond and to generate HCl gas and a compound with an Si-bonds that is more stable than the compound including the Si—Cl bond; a second cleaning gas supply configured to supply, into the processing space, a second cleaning gas that is selected to react with the HCl gas to generate a compound having a lower toxicity than HCl gas; memory storing instructions; and a controller including one or more processors configured to individually or collectively execute the instructions, wherein the instructions, when executed by the one or more processors individually or collectively, cause the substrate treatment apparatus to: control the first cleaning gas supply to supply the first cleaning gas into the processing space, and control the second cleaning gas supply to supply the second cleaning gas into the processing space.

### BRIEF DESCRIPTION OF DRAWINGS

The above and other aspects and features of the present disclosure will be more clearly understood from the following detailed description, taken in conjunction with the accompanying drawings, in which:

FIG. 1 is a vertical cross-sectional view illustrating a substrate treatment apparatus according to one or more embodiments of the present disclosure;

FIG. 2 is a flowchart illustrating an apparatus cleaning method according to one or more embodiments of the present disclosure;

FIG. 3 is a vertical cross-sectional view illustrating an example of opening a shutter before a first cleaning gas is supplied to the substrate treatment apparatus of FIG. 1;

FIG. 4 is a vertical cross-sectional view illustrating an example of supplying the first cleaning gas to the substrate treatment apparatus of FIG. 1 in the first cleaning gas supply operation of FIG. 2;

FIG. 5 is a vertical cross-sectional view illustrating an example of the substrate treatment apparatus of FIG. 1 operating in the vacuum pressure forming operation of FIG. 2;

FIG. 6 is a vertical cross-sectional view illustrating an example of the substrate treatment apparatus of FIG. 1 operating in the second cleaning gas supply operation of FIG. 2;

FIG. 7 is a vertical cross-sectional view illustrating a substrate treatment apparatus according to one or more embodiments of the present disclosure;

FIG. 8 is a graph illustrating the residual amount of HCl over time in a processing space when the substrate treatment apparatus is test-operated to perform only the HCl gas removal operation of FIG. 2; and

FIG. 9 is a graph illustrating the residual amount of HCl over time in a processing space when the substrate treatment apparatus is test-operated to perform the first cleaning gas supply operation and the HCl gas removal operation of FIG. 2.

### DETAILED DESCRIPTION

In the following description, like reference numerals refer to like elements throughout the specification.

As used herein, a plurality of “units”, “modules”, “members”, and “blocks” may be implemented as a single component, or a single “unit”, “module”, “member”, and “block” may include a plurality of components.

It will be understood that when an element is referred to as being “connected” with or to another element, it can be directly or indirectly connected to the other element, wherein the indirect connection may include “connection via a wireless communication network”.

Also, when a part “includes” or “comprises” an element, unless there is a particular description contrary thereto, the part may further include other elements, not excluding the other elements.

Throughout the description, when a member is “on” another member, this includes not only a configuration where the member is in contact with the other member, but also a configuration where there is another member between the two members.

As used herein, the expressions “at least one of a, b or c” and “at least one of a, b and c” indicate “only a,” “only b,” “only c,” “both a and b,” “both a and c,” “both b and c,” and “all of a, b, and c.”

It will be understood that, although the terms “first”, “second”, “third”, etc., may be used herein to describe various elements, the disclosure is not be limited by these terms, and these terms are only used to distinguish one element from another element.

As used herein, the singular forms “a,” “an” and “the” are intended to include the plural forms as well, unless the context clearly indicates otherwise.

With regard to any method or process described herein, an identification code may be used for the convenience of the description but is not intended to illustrate the order of each step or operation. Each step or operation may be implemented in an order different from the illustrated order unless the context clearly indicates otherwise. One or more steps or operations may be omitted unless the context of the disclosure clearly indicates otherwise.

The various actions, acts, blocks, steps, or the like in the flow diagrams may be performed in the order presented, in a different order, or simultaneously. Further, in one or more embodiments, some of the actions, acts, blocks, steps, or the like may be omitted, added, modified, skipped, or the like without departing from the scope of the disclosure.

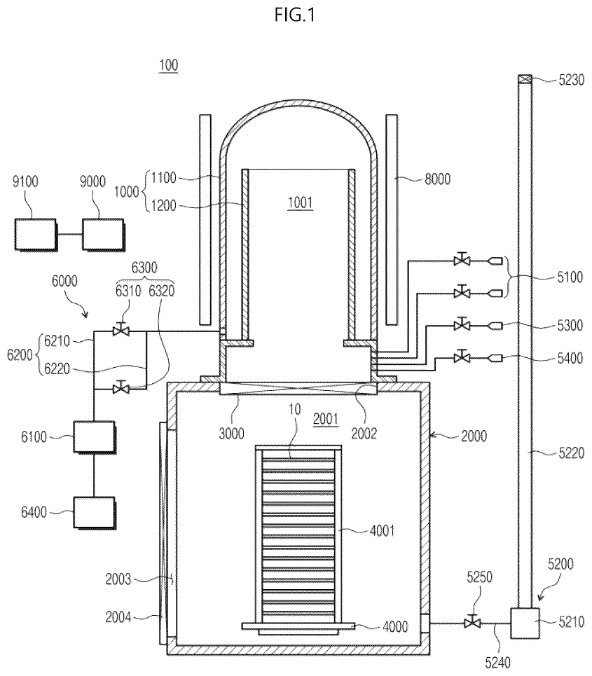

FIG. 1 is a vertical cross-sectional view illustrating a substrate treatment apparatus 100 according to one or more embodiments of the present disclosure.

Referring to FIG. 1, the substrate treatment apparatus 100 according to one or more embodiments of the present disclosure is an apparatus for processing a substrate. According to one or more embodiments, the substrate treatment apparatus 100 may be a deposition apparatus that deposits oxide films on surfaces of a substrates 10. For example, the substrate treatment apparatus 100 may be an apparatus that performs a DCS MTO process on the substrate 10. Alternatively, the substrate treatment apparatus 100 may be provided as various types of substrate treatment apparatuses capable of performing an apparatus cleaning method according to one or more embodiments of the present disclosure.

According to one or more embodiments, the substrate treatment apparatus 100 may include a substrate treatment chamber 1000, a substrate waiting chamber 2000, a shutter 3000, a substrate support 4000, a processing gas supply 5100, a first cleaning gas supply 5200, a second cleaning gas supply 5300, a partial pressure ratio control gas supply 5400, a vacuum 6000, a temperature controller 8000, and a controller 9000.

The substrate treatment chamber 1000 may have a processing space 1001. The processing space 1001 may be formed in the substrate treatment chamber 1000. Substrates 10 may be processed in the processing space 1001. According to one or more embodiments, the substrate treatment chamber 1000 may include an outer tube 1100 and an inner tube 1200.

The outer tube 1100 and the inner tube 1200 may be made of quartz (SiO₂). Each of the outer tube 1100 and the inner tube 1200 may be a cylindrical shape with a vertical longitudinal direction.

The upper surface of the outer tube 1100 may be covered with a dome structure. The outer tube 1100 may have an open bottom.

The inner tube 1200 may be inside the outer tube 1100. The inner tube 1200 may be positioned such that it is spaced apart from the outer tube 1100. The inner tube 1200 may have an open top and open bottom. The lower end between the outer tube 1100 and the inner tube 1200 may be sealed.

An exhaust hole through which gas in the processing space 1001 is exhausted may be formed at the lower end of the area of the side wall of the outer tube 1100 that corresponds to the inner tube 1200. Inlet holes through which gases to be supplied to the processing space 1001 are introduced may be formed at the lower end of the side wall of the outer tube 1100 that is lower than the lower end of the inner tube 1200.

Since the substrate treatment chamber 1000 is provided with the structure described above, gases introduced into the processing space 1001 through the inlet holes may rise along the inside of the inner tube 1200, and then descend along the space between the outer tube 1100 and the inner tube 1200 to be exhausted through the exhaust hole. Therefore, the gases introduced into the processing space 1001 may be guided by the outer tube 1100 and the inner tube 1200 to pass through both the upper and lower parts of the processing space 1001.

The substrate waiting chamber 2000 may have a waiting space 2001. The waiting space 2001 may be formed in the substrate waiting chamber 2000. Substrates 10 wait before being introduced into the substrate treatment chamber 1000, or after being discharged from the substrate treatment chamber 1000, in the waiting space 2001. According to one or more embodiments, the upper wall of the substrate waiting chamber 2000 may be connected to the lower end of the substrate treatment chamber 1000.

An opening 2002 may be formed on the upper wall of the substrate waiting chamber 2000 and the substrates 10 may move between the processing space 1001 and the waiting space 2001. According to one or more embodiments, a substrate support 4000 which supports a boat 4001 (described below) supporting substrates 10 may pass through the opening 2002 to move between the processing space 1001 and the waiting space 2001.

A substrate entrance 2003 may be formed on the side wall of the substrate waiting chamber 2000 through which substrates 10 move into and out of the waiting space 2001. According to one or more embodiments, the boat 4001 supporting substrates 10 may move in and out of the waiting space 2001 through the substrate entrance 2003. Alternatively, the boat 4001 may be fixed to the substrate support 4000, and the substrates 10 may be moved in and out of the waiting space 2001 through the substrate entrance 2003. The substrates 10 and/or the boat 4001 may be moved between the inside and outside of the waiting space 2001 through the substrate entrance 2003 by a separate transport device such as a robot arm. In one or more embodiments, a door 2004 covers the substrate entrance 2003.

The shutter 3000 opens and closes the opening 2002. According to one or more embodiments, the shutter 3000 may open the opening 2002 when moving the substrate 10 through the opening 2002, or when moving gas between the processing space 1001 and the waiting space 2001 through the opening 2002. And the shutter 3000 may close the opening 2002 when a substrate processing process is performed in the processing space 1001 or when the internal pressure of the processing space 1001 is a vacuum pressure. In addition, if necessary, the shutter 3000 may open and close the opening 2002. The processing space 1001 may be sealed when the shutter 3000 is closed.

The substrate support 4000 may support the substrates 10 within the processing space 1001 and the waiting space 2001. According to one or more embodiments, the substrate support 4000 may support a boat 4001 capable of supporting a plurality of substrates 10. The boat 4001 may be detachably placed on the substrate support 4000. The substrate support 4000 may move between the processing space 1001 and the waiting space 2001 through the opening 2002 while supporting the substrates 10 or the boat 4001 supporting the substrates 10. According to one or more embodiments, a driver or actuator may be connected to the lower surface of the substrate support 4000 to move the substrate support 4000 up and down between the processing space 1001 and the waiting space 2001 through the opening 2002.

The processing gas supply 5100 may supply processing gas into the processing space 1001. The processing gas may react within the processing space 1001 to process the substrate 10. According to one or more embodiments, the processing gas may be provided as a deposition gas for depositing oxide films on the surfaces of the substrates 10. A plurality of types of processing gases may be provided. The processing gases may be supplied to the processing space 1001 through some of the respective inlet holes formed in the substrate treatment chamber 1000 by separate processing gas supplies 5100. For example, the processing gas may include DCS (SiH₂Cl₂) gas and 2N₂O gas. The DCS gas and 2N₂O gas react within the processing space 1001 to deposit a SiO₂ film on the surfaces of the substrates 10. In addition, N₂ gas and HCl gas may be generated. The reaction formula for the reaction of the DCS gas and 2N₂O gas in the processing space 1001 is illustrated in the following Reaction Formula 1.

SiH₂Cl₂ (DCS)+2N₂O→SiO₂+2N₂+HCl Reaction Formula 1

Referring to Reaction Formula 1, HCl gas may be generated within the processing space 1001 when the reaction occurs while the process is in progress within the processing space 1001. Accordingly, compounds including Si—Cl bonds together with compounds including Si—O bonds may be deposited on surfaces within the processing space 1001 and on the inner surfaces of the exhaust line 6200 (described below) through which gas within the processing space 1001 may pass. The compounds including Si—Cl bonds may react with a gas including a hydrogen (H) element to generate compounds including Si-bonds other than Si—Cl bonds and HCl gas. In this case, if the generated compounds including Si-bonds are not more stable than the compounds including Si—Cl bonds, the compounds including Si—Cl bonds may be deposited again due to a reversible reaction. This causes removal efficiency of the HCl gas within the processing space 1001 to decrease.

The first cleaning gas supply 5200 may supply the first cleaning gas into the processing space 1001. The first cleaning gas may react with the compounds including Si—Cl bonds to generate compounds including Si-bonds that are more stable than compounds including Si—Cl bonds, and HCl gas. For example, the first cleaning gas may be a gas including H₂O, HF₂, PH₃, AsH₃, and/or IPA ((CH₃)₂CHOH). The reaction formulas of each of the examples involving compounds with Si—Cl bonds are illustrated in the following reaction formulas 2 to 6.

Si—Cl bond+H₂O →Si—O bond+HC Reaction Formula 2

Si—Cl bond+HF₂→Si—F bond+HCl Reaction Formula 3

Si—Cl bond+PH₃→Si—P bond+HCl Reaction Formula 4

Si—Cl bond +AsH₃→Si—As bond+HCl Reaction Formula 5

Si—Cl bond+(CH₃)₂CHOH→Si—OCH(CH₃)₂ bond+HCl Reaction Formula 6

Compounds including Si—O bonds, Si—F bonds, Si—P bonds, Si—As bonds and Si—OCH(CH₃)₂ bonds are more stable than compounds including Si—Cl bonds. Therefore, if the first cleaning gas as described above is supplied to the processing space 1001 where compounds including Si—Cl bonds are deposited, compounds with Si—Cl bonds may not be generated again by a reversible reaction.

In contrast, the first cleaning gas may be provided as various gases that may react with the compounds including Si—Cl bonds to generate compounds including Si-bonds that are more stable than compounds including Si—Cl bonds, and HCl gas.

According to one or more embodiments, the first cleaning gas may be air including H₂O. That is, the first cleaning gas may be provided as air having a specific humidity or higher. The specific humidity may be determined by simulation and/or test operation of the substrate treatment apparatus 100. For example, the first cleaning gas may be provided as air from outside the substrate treatment apparatus 100. Generally, the air inside a fabrication facility where semiconductor equipment is provided has a humidity of about 40%. Therefore, the first cleaning gas may be provided as air from inside a fabrication facility where the substrate treatment apparatus 100 is provided. As used herein, the term “air” refers to gas generally similar to the mixture of gases that surround the Earth, such as ambient air, where such “air” may be filtered as otherwise described herein.

According to one or more embodiments, the first cleaning gas supply 5200 may include an air pump 5210, an external air intake pipe 5220, a filter 5230, an air supply line 5240 and a valve 5250.

The air pump 5210 may generate a driving force to move external air to the waiting space 2001 and/or the processing space 1001.

The external air intake pipe 5220 may be connected between the outside of the substrate treatment apparatus 100 and the waiting space 2001 or the processing space 1001 and thus may act as a passage through which external air supplied to the air pump 5210 passes.

According to one or more embodiments, an end of the external air intake pipe 5220 may be located outside the substrate treatment apparatus 100, and the other end of the external air intake pipe 5220 may be connected to the waiting space 2001 or the processing space 1001.

A filter 5230 may be installed in the external air intake pipe 5220 and/or the air supply line 5240. The filter 5230 may filter foreign substances introduced from the external air.

The air supply line 5240 may be connected between the air pump 5210 and the waiting space 2001 or the processing space 1001. Air introduced into the air pump 5210 through the external air intake pipe 5220 may be introduced into the processing space 1001 or the waiting space 2001 along the air supply line 5240 by the driving force of the air pump 5210. An end of the air supply line 5240 may be connected to the air pump 5210, and the other end of the air supply line 5240 may be connected to the processing space 1001 or the waiting space 2001. According to one or more embodiments, the other end of the air supply line 5240 may be connected to the lower end of the side wall of the substrate waiting chamber 2000. Therefore, the air supplied to the lower part of the waiting space 2001 by the first cleaning gas supply 5200 may sequentially pass through the waiting space 2001 and the processing space 1001 and be exhausted. Therefore, the first cleaning gas supply 5200 may function as a ventilation gas supply that supplies external air to the waiting space 2001 and the processing space 1001 as a ventilation gas that ventilates the waiting space 2001 and the processing space 1001. Therefore, according to one or more embodiments, the substrate treatment apparatus 100 may not need to have the first cleaning gas supply 5200 and the ventilation gas supply separately.

The second cleaning gas supply 5300 supplies the second cleaning gas to the processing space 1001. The second cleaning gas is selected to react with HCl gas to generate a compound having a lower toxicity than HCl gas. In one or more embodiments, toxicity may be measured based on the National Fire Protection Association LC50 toxicity scale; however, the disclosure is limited thereto, and other toxicity scales may be used. According to one or more embodiments, the second cleaning gas may be NH₃ gas. NH₃ is in a gaseous state at room temperature and may be supplied to the processing space 1001 in a gaseous state. NH₃ may react with HCl to form NH₄Cl. NH₄Cl has a lower toxicity than HCl gas. The reaction formula for NH₃ reacting with HCl is illustrated in the reaction formula 7 below.

HCl+NH₃→NH₄Cl Reaction Formula 7

However, NH₃ may react with compounds including Si—Cl bonds to generate compounds including Si—N bonds and HCl. The reaction formula for NH₃ reacting with compounds including Si—Cl bonds is illustrated in the reaction formula 8 below.

Si—Cl bond+NH₃→Si—N bond+HCl Reaction Formula 8

Compounds including Si—N bonds are an unstable compared to compounds including Si—Cl bonds. Therefore, if NH₃ gas is directly supplied to the processing space 1001 wherein the compounds including Si—Cl bonds are deposited on the surface, compounds including Si—Cl bonds are deposited again due to a reversible reaction. The compounds including Si—Cl bonds deposited again may cause an increase in the HCl removal time. However, if the first cleaning gas is preemptively supplied to the processing space 1001 before the second cleaning gas is supplied to the processing space 1001 where the compounds including Si—Cl bonds are deposited, the compounds including Si—Cl bonds are removed by the first cleaning gas, and compounds including more stable Si-bonds are generated. Therefore, if the second cleaning gas is supplied to remove HCl after the compounds including Si—Cl bonds deposited in the processing space 1001 are removed by the first cleaning gas, HCl may be removed more efficiently because compounds including Si—Cl bonds are not redeposited. According to one or more embodiments, the second cleaning gas may be supplied to the processing space 1001 through at least one of the inlet holes formed in the substrate treatment chamber 1000.

The partial pressure ratio control gas supply 5400 may supply the partial pressure ratio control gas to the processing space 1001. The partial pressure ratio control gas may control the partial pressure of the second cleaning gas within the processing space 1001. The reaction efficiency of the second cleaning gas may be optimized when the partial pressure of the second cleaning gas within the processing space 1001 is maintained within an appropriate range. The range of the partial pressure of the second cleaning gas may be set through simulation and/or test operation. According to one or more embodiments, the partial pressure ratio control gas may be an inert gas. For example, the partial pressure ratio control gas may be N₂ gas. According to one or more embodiments, the pressure ratio control gas 5400 may be introduced into the processing space 1001 through at least one of the inlet holes of the substrate treatment chamber 1000.

The vacuum 6000 may form the internal pressure of the processing space 1001 into a vacuum pressure. According to one or more embodiments, the vacuum 6000 may include an exhaust pump 6100, an exhaust line 6200, and a valve 6300.

The exhaust pump 6100 may generate power to exhaust gas within the processing space 1001.

The exhaust line 6200 may be connected between the exhaust pump 6100 and the processing space 1001. Therefore, gas may move between the processing space 1001 and the exhaust pump 6100. According to one or more embodiments, the exhaust line 6200 may include a first exhaust line 6210 and a second exhaust line 6220. An end of the exhaust line 6200 may be connected to the exhaust pump 6100. And the other end of the exhaust line 6200 may be connected to the exhaust hole formed at the lower end of the area corresponding to the inner tube 1200 of the side wall of the outer tube 1100.

The first exhaust line 6210 may have a first inner diameter. And, the second exhaust line 6220 may have a second inner diameter larger than the first inner diameter. Therefore, the flow rate of the gas exhausted through the first exhaust line 6210 is smaller than the flow rate of the gas exhausted through the second exhaust line 6220. Therefore, a much more rapid pressure change may occur in the case of exhausting through the second exhaust line 6220 compared to the case of exhausting through the first exhaust line 6210 when forming a vacuum pressure for the processing space 1001. According to one or more embodiments, the gas within the processing space 1001 may be exhausted at a first flow rate through the first exhaust line 6210 and at a second flow rate greater than the first flow rate through the second exhaust line 6220 when exhaust of the processing space 1001 is performed.

The valve 6300 may open and close the exhaust line 6200. According to one or more embodiments, the valve 6300 may include a first valve 6310 and a second valve 6320. The first valve 6310 may open and close the first exhaust line 6210. And, the second valve 6320 may open and close the second exhaust line 6220.

The gas exhausted by the vacuum 6000 may be delivered to the scrubber 6400.

The temperature controller 8000 may control the temperature in the processing space 1001 to an appropriate temperature range during each process performed in the substrate treatment apparatus 100, such as during the substrate processing process, during the first cleaning gas supply, and/or during the second cleaning gas supply. According to one or more embodiments, the temperature controller 8000 may include a heater that surrounds the side of the substrate treatment chamber 1000 and generates heat according to an electrical method. In addition, the temperature controller 8000 may include a cooler that may cool the processing space 1001. The cooler may include a thermoelectric element or a cooling path through which a cooling fluid passes.

The controller 9000 may control the components of the substrate treatment apparatus 100. According to one or more embodiments, the controller 9000 may control the components of the substrate treatment apparatus 100 during the substrate processing process and the apparatus cleaning method described below.

The controller 9000 may be operably connected to memory 9100. The memory 9100 may be implemented as at least one of a volatile memory (e.g.: a dynamic RAM (DRAM), a static RAM (SRAM), or a synchronous dynamic RAM (SDRAM), etc.) or a non-volatile memory (e.g.: an one time programmable ROM (OTPROM), a programmable ROM (PROM), an erasable and programmable ROM (EPROM), an electrically erasable and programmable ROM (EEPROM), a mask ROM, a flash ROM, a flash memory (e.g.: NAND flash or NOR flash, etc.), a hard drive, or a solid state drive (SSD)). In the case of a memory that can be attached to or detached from the substrate treatment apparatus 100, the memory 9100 may be implemented in various forms such as a memory card (e.g., compact flash (CF), secure digital (SD), micro secure digital (Micro-SD), mini secure digital (Mini-SD), extreme digital (xD), a multi-media card (MMC), etc.), an external memory that can be connected to a USB port (e.g., a USB memory), etc.

The controller 9000 may be implemented as one or more processors configured to operate individually or collectively. The one or more processors may include a digital signal processor (DSP) processing digital signals, a microprocessor, and a time controller (TCON). However, the disclosure is not limited thereto, and the controller 9000 may include one or more of a central processing unit (CPU), a micro controller unit (MCU), a micro processing unit (MPU), a controller, an application processor (AP), a graphics-processing unit (GPU) or a communication processor (CP), and an advanced reduced instruction set computer (RISC) machines (ARM) processor, or may be defined by the terms. Also, the controller 9000 may be implemented as a system on chip (SoC) having a processing algorithm stored therein or large scale integration (LSI), or in the form of a field programmable gate array (FPGA). The one or more processors of the controller 9000 may, individually or collectively, perform various functions by executing computer executable instructions stored in the memory 9100. The memory 9100 may be integral to the controller 9000 or may be separately provided.

Hereinafter, an apparatus cleaning method according to one or more embodiments of the present disclosure will be described with reference to drawings.

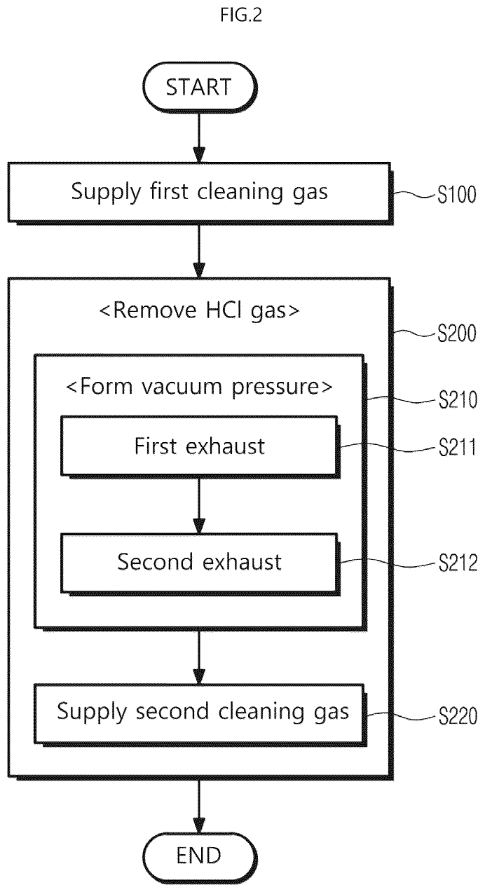

FIG. 2 is a flowchart illustrating an apparatus cleaning method according to one or more embodiments of the present disclosure.

Referring to FIGS. 1 and 2, the apparatus cleaning method is a method for cleaning a target area 1001, 2001 of a substrate treatment apparatus 100. According to one or more embodiments, the target area 1001, 2001 may include a processing space 1001 and/or an exhaust line 6200 of the substrate treatment apparatus 100. In the description below, the target of the apparatus cleaning method is exemplified by the substrate treatment apparatus 100 of FIG. 1, but, unlike this, the apparatus cleaning method of the present disclosure may be applied to various types of apparatuses in which compounds including Si—Cl bonds may be deposited and HCl gas may remain inside.

The substrate processing process may be directly performed in the processing space 1001, and gas inside the processing space 1001 may be exhausted through the exhaust line 6200 during the substrate processing process. Therefore, HCl gas may remain in the processing space 1001 and the exhaust line 6200, and as described above, compounds including Si—Cl bonds may be deposited on the internal surfaces of the processing space 1001 and the exhaust line 6200.

According to one or more embodiments, the apparatus cleaning method may include a first cleaning gas supply operation S100 and an HCl gas removal operation S200. The apparatus cleaning method in the substrate treatment apparatus 100 may be performed under the control of the controller 9000.

The first cleaning gas may be supplied to the target area 1001, 2001 in the first cleaning gas supply operation S100. The first cleaning gas may be provided as air having a certain humidity or higher. The first cleaning gas may be air obtained outside the substrate treatment apparatus 100. According to one or more embodiments, the first cleaning gas supply operation S100 may be performed at atmospheric pressure. Exhaust may be performed within the target area 1001, 2001 to spread the first cleaning gas throughout the entire area of the target area 1001, 2001 and to maintain the internal pressure of the target area 1001, 2001 within a certain range.

According to one or more embodiments, the controller 9000 may control each component of the substrate treatment apparatus 100 required to perform the first cleaning gas supply operation S100 in the first cleaning gas supply operation S100. The controller 9000 may control the temperature controller 8000 to maintain the internal temperature of the processing space 1001 within an appropriate range in each of the operations described below. The appropriate range of the temperature may be set through simulation and/or test operation.

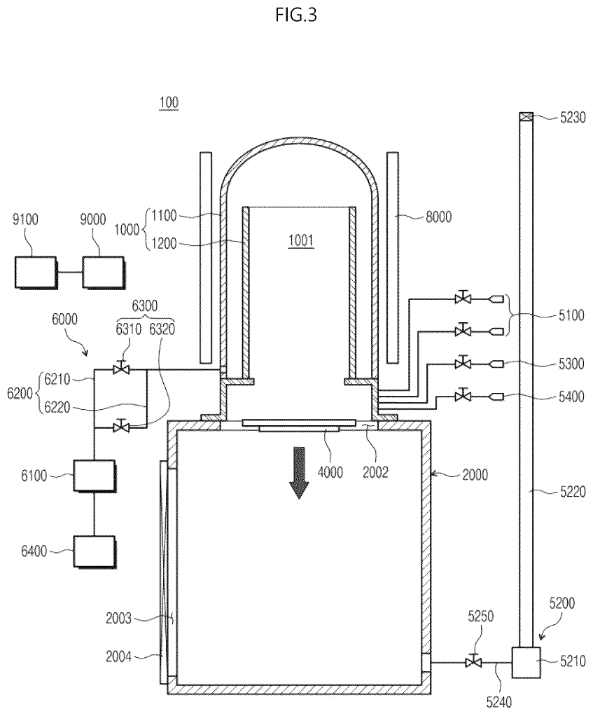

FIG. 3 is a vertical cross-sectional view illustrating an example of opening a shutter 3000 before a first cleaning gas is supplied to the substrate treatment apparatus 100 of FIG. 1.

Referring to FIG. 3, the first cleaning gas supply operation S100 may be performed in a state where the shutter 3000 is opened. Accordingly, the processing space 1001 and the waiting space 2001 may be connected to each other. Therefore, the first cleaning gas flowing into the waiting space 2001 may flow into the processing space 1001 through the opening 2002. Therefore, the first cleaning gas supply 5200 can be connected to the substrate waiting chamber 2000 and the first cleaning gas supply 5200 can perform the function of the ventilation gas supply as described above. In addition, the substrate support 4000 may be moved into the waiting space 2001 after the shutter 3000 is opened for smooth diffusion of the first cleaning gas in the processing space 1001.

According to one or more embodiments, the controller 9000 may control the shutter 3000 to open the opening 2002 and control the substrate support 4000 to be moved into the waiting space 2001 before supplying the first cleaning gas to the target area 1001, 2001.

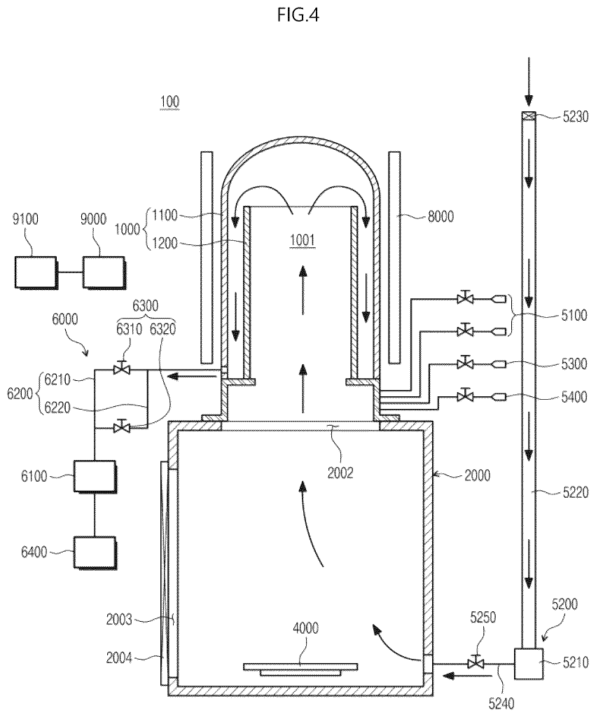

FIG. 4 is a vertical cross-sectional view illustrating an example of supplying the first cleaning gas to the substrate treatment apparatus 100 of FIG. 1 in the first cleaning gas supply operation S100 of FIG. 2.

Referring to FIG. 4, the controller 9000 may control the first cleaning gas supply 5200 to supply the first cleaning gas to the target area 1001, 2001 while maintaining the shutter 3000 open to make the opening 2002 open and positioning the substrate support 4000 in the waiting space 2001 as described above in the first cleaning gas supply operation S100. For example, the controller 9000 may open the valve 5250 and operate the air pump 5210 in the first cleaning gas supply operation S100.

H₂O included in the first cleaning gas may react with compounds including Si—Cl bonds to form compounds including Si—O bonds and HCl gas when the first cleaning gas supply operation S100 is performed as described above. A reversible reaction in which compounds including Si—Cl bonds is generated again may be reduced or prevented because compounds including Si—O bonds are more stable than compounds including Si—Cl bonds.

HCl gas may be removed within the target area 1001, 2001 in the HCl gas removal operation S200 after the first cleaning gas supply operation S100. According to one or more embodiments, the HCl gas removal operation S200 may include a vacuum pressure forming operation S210 and a second cleaning gas supply operation S220.

According to one or more embodiments, the controller 9000 may control each component of the substrate treatment apparatus 100 required to perform the HCl gas removal operation S200 in the HCl gas removal operation S200.

The vacuum pressure forming operation S210 may be performed after the first cleaning gas supply operation S100 and before the second cleaning gas supply operation S220. The pressure of the target area 1001, 2001 may be formed as vacuum pressure in the vacuum pressure forming operation S210. According to one or more embodiments, the vacuum pressure forming operation S210 may include a first exhaust operation S211 and a second exhaust operation S212.

Gas inside the target area 1001, 2001 may be exhausted at a first flow rate in the first exhaust operation S211. The second exhaust operation S212 may be performed after the first exhaust operation S211. Gas inside the target area 1001, 2001 may be exhausted at a second flow rate in the second exhaust operation S212. The second flow rate may be greater than the first flow rate.

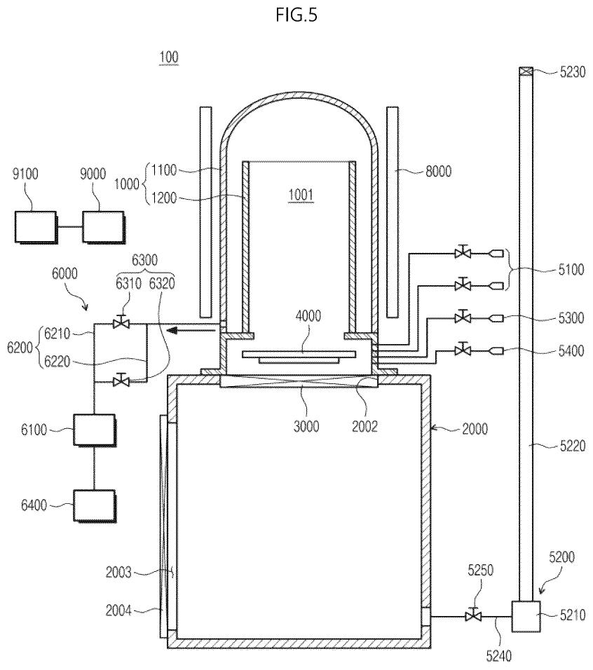

FIG. 5 is a vertical cross-sectional view illustrating an example of the substrate treatment apparatus 100 of FIG. 1 operating in the vacuum pressure forming operation S210 of FIG. 2.

Referring to FIG. 5, the controller 9000 may control each component of the substrate treatment apparatus 100, such as the vacuum 6000, to perform the vacuum pressure forming operation S210 in the vacuum pressure forming operation S210.

According to one or more embodiments, the controller 9000 may close the shutter 3000 to seal the processing space 1001 before exhaust is performed in the vacuum pressure forming operation S210. At this time, if the substrate support 4000 must be positioned in the processing space 1001 to close the shutter 3000 according to a type of the substrate treatment apparatus 100, the controller 9000 may move the substrate support 4000 into the processing space 1001 before closing the shutter 3000.

Thereafter, the first exhaust operation S211 may be performed. According to one or more embodiments, the controller 9000 may open the first valve 6310 and operate the exhaust pump 6100 in the first exhaust operation S211. Therefore, gas in the processing space 1001 may be exhausted at the first flow rate along the first exhaust line 6210 in the first exhaust operation S211. The controller 9000 may control the first valve 6310 to open the first exhaust line 6210 for a specific time and then close the first exhaust line 6210 In the first exhaust operation S211. The specific time for which the first exhaust line 6210 is opened may be set by simulation and/or test operation according to the type of the substrate treatment apparatus 100 and other conditions.

Thereafter, the second exhaust operation S212 may be performed. According to one or more embodiments, the controller 9000 may keep the first valve 6310 closed, open the second valve 6320 and operate the exhaust pump 6100 in the second exhaust operation S212. Therefore, gas within the processing space 1001 may be exhausted at a second flow rate greater than the first flow rate along the second exhaust line 6220 in the second exhaust operation S212.

As described above, since the vacuum pressure forming operation S210 is sequentially performed from exhaust at a small flow rate to exhaust at a large flow rate, a rapid change of pressure at the beginning of exhaust, which may cause a relatively large pressure difference, may be prevented, thereby preventing damage to the substrate treatment apparatus 100, such as the substrate treatment chamber 1000, due to a rapid pressure change.

As described above, when the internal pressure of the target area 1001, 2001 reaches a vacuum state, the reaction rate between the second cleaning gas and the HCl gas may be increased because other gas molecules within the target area 1001, 2001 that interfere with the collision between the second cleaning gas and the HCl gas are removed.

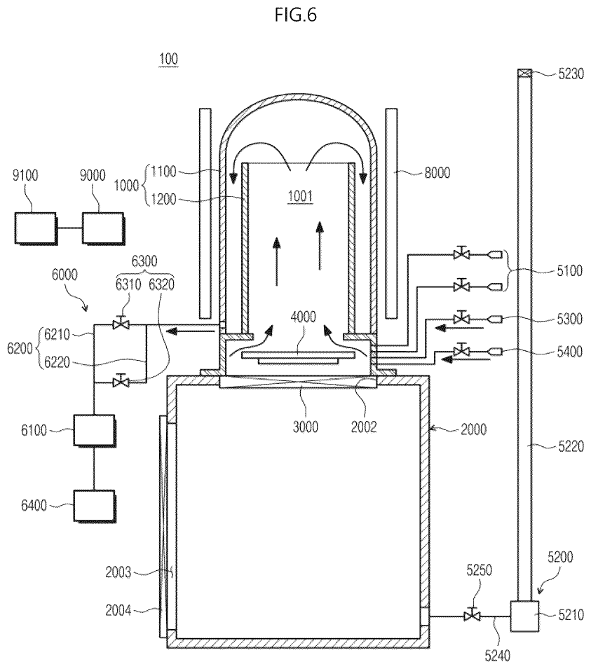

FIG. 6 is a vertical cross-sectional view illustrating an example of the substrate treatment apparatus 100 of FIG. 1 operating in the second cleaning gas supply operation S220 of FIG. 2.

Referring to FIG. 6, the second cleaning gas supply operation S220 may be performed after the vacuum pressure forming operation S210. the second cleaning gas may be supplied to remove HCl gas within the target area 1001, 2001 and generate a compound having a lower toxicity than HCl gas in the second cleaning gas supply operation S220

According to one or more embodiments, the controller 9000 may control the vacuum 6000 to continuously perform exhaust and cause the shutter 3000 to remain closed to maintain the vacuum pressure within the processing space 1001 formed in the vacuum pressure forming operation S210, in the second cleaning gas supply operation S220. In addition, the controller 9000 may control the second cleaning gas supply 5300 to supply the second cleaning gas into the processing space 1001. And the controller 9000 may control the partial pressure ratio control gas supply 5400 to supply the partial pressure ratio control gas together with the second cleaning gas into the processing space 1001 to form an appropriate range of partial pressure ratios of the second cleaning gas into the processing space 1001 for efficient reaction of the second cleaning gas.

Since the HCl gas removal operation S200 is performed as described above, the HCl remaining in the processing space 1001 and the exhaust line 6200 is removed by the reaction with the second cleaning gas, and a generated substance less toxic than HCl may be discharged outside the substrate treatment apparatus 100.

According to one or more embodiments, the controller 9000 may control the second cleaning gas supply 5300 and the partial pressure ratio control gas supply 5400 to stop supplying the second cleaning gas and the partial pressure ratio control gas in order to completely discharge the second cleaning gas and the reaction byproducts remaining in the processing space 1001 and the exhaust line 6200, and then operate the vacuum 6000 for a certain period of time.

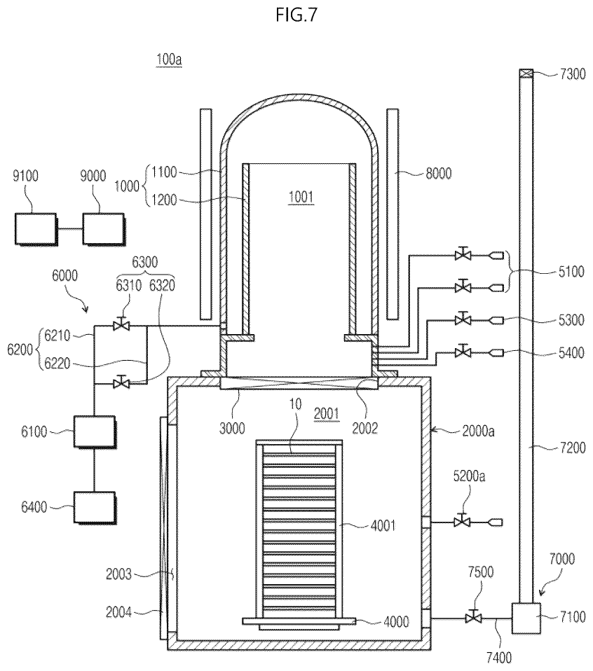

FIG. 7 is a vertical cross-sectional view illustrating a substrate treatment apparatus 100a according to one or more embodiments of the present disclosure.

Referring to FIG. 7, according to one or more embodiments, the substrate treatment apparatus 100a may include a first cleaning gas supply 5200a and a ventilation gas supply 7000 separately.

The first cleaning gas supply 5200a may be connected to the lower part of the waiting chamber 2000a separately from the ventilation gas supply 7000 and supply the first cleaning gas to the lower part of the waiting space 2001.

Other features such as the components, structure and operation method of the ventilation gas supply 7000 may be identical or similar to the first cleaning gas supply 5200 of FIG. 1. For example, ventilation gas supply 7000 may include air pump 7100 (see, e g., air pump 5210), air intake pipe 7200 (see, e.g., air intake pipe 5220), filter 7300 (see, e.g., filter 5230), air supply line 7400 (see, e.g., air supply line 5240), and valve 7500 (see, e.g., valve 5250).

Therefore, the supply of the first cleaning gas in the first cleaning gas supply operation S100 of FIG. 2 may be performed by the first cleaning gas supply 5200a, and the ventilation of the waiting space 2001 and the processing space 1001 may be performed by the ventilation gas supply 7000.

As described above, since the first cleaning gas supply 5200a are separate from the ventilation gas supply 7000, even when the external air of the substrate treatment apparatus 100a is not suitable for use in the apparatus cleaning method of FIG. 2, such as when the humidity of the external air of the substrate treatment apparatus 100a is in a range where it is difficult to perform the first cleaning gas supply operation S100 of FIG. 2, the substrate treatment apparatus 100a of FIG. 7 may perform the apparatus cleaning method of FIG. 2 by using the first cleaning gas supply 5200a provided separately from the ventilation gas supply 7000.

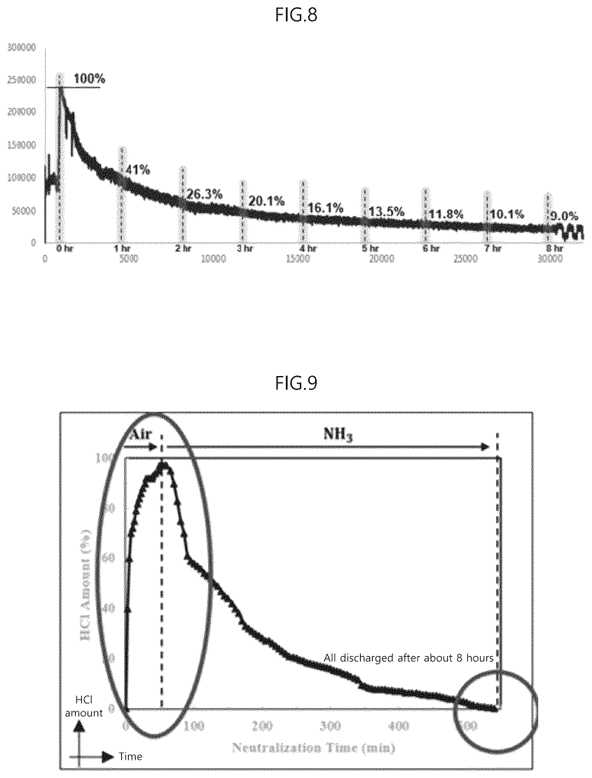

FIG. 8 is a graph illustrating the residual amount of HCl over time in a processing space 1001 when the substrate treatment apparatus is test-operated to perform only the HCl gas removal operation S200 of FIG. 2. FIG. 9 is a graph illustrating the residual amount of HCl over time in a processing space 1001 when the substrate treatment apparatus is test-operated to perform the first cleaning gas supply operation S100 and the HCl gas removal operation S200 of FIG. 2.

Referring to FIGS. 1, 2, 8, and 9, the substrate treatment apparatus 100 used in the test operation is as an apparatus of which the first cleaning gas supply 5200 may also perform the function of the ventilation gas supply, as in FIG. 1. In the cases of FIGS. 8 and 9, all conditions of the vacuum pressure formation operation S210 and the second cleaning gas supply operation S220 were set identically.

Referring to FIG. 8, when the substrate treatment apparatus 100 does not perform the first cleaning gas supply operation S100 and only performs the HCl gas removal operation S200, compounds including Si—Cl bonds are regenerated by a reversible reaction, so the process of the compounds including Si—Cl bonds being decomposed again, and HCl gas being generated, is repeated, and it may be confirmed that about 9% of the HCl gas remains in the processing space 1001 eight hours after the apparatus cleaning method start.

Referring to FIG. 9, when the substrate treatment apparatus 100 performs the HCl gas removal operation S200 after performing the first cleaning gas supply operation S100, compounds including Si—Cl bonds are removed and compounds including Si—O bonds, which are more stable than the Si—Cl bonds, are generated. Therefore, the compounds including Si—Cl bonds are not regenerated by a reversible reaction, and it may be confirmed that no HCl remains in the processing space 1001 eight hours after the apparatus cleaning method began.

As described above, the apparatus cleaning method and the substrate treatment apparatuses 100, 100a performing the same according to one or more embodiments of the present disclosure may remove compounds including Si—Cl bonds deposited inside the substrate treatment apparatus 100, 100a that may react with the cleaning gas and become a source of HCl gas generation without a reversible reaction in which compounds including Si—Cl bonds are deposited again. Therefore, the apparatus cleaning method and the substrate treatment apparatuses 100, 100a performing the same according to the embodiments of the present disclosure may increase the removal efficiency of HCl gas inside the substrate treatment apparatus 100, 100a.

While the present disclosure has been described with reference to embodiments thereof, it will be apparent to those of ordinary skill in the art that various changes and modifications can be made thereto without departing from the spirit and scope of the present disclosure as set forth in the following claims.

What is claimed is:

1. An apparatus cleaning method comprising:
supplying a first cleaning gas to a target area of a substrate treatment apparatus, wherein the first cleaning gas is selected to react with a compound including Si—Cl bonds; and
removing HCl gas from the target area after the supplying the first cleaning gas to the target area.

2. The apparatus cleaning method of claim 1, wherein the first cleaning gas is air comprising a humidity equal to or greater than a specific humidity.

3. The apparatus cleaning method of claim 2, wherein the air is obtained outside the substrate treatment apparatus.

4. The apparatus cleaning method of claim 1, further comprising:
exhausting gases from the target area during the supplying the first cleaning gas to the target area.

5. The apparatus cleaning method of claim 1, wherein the removing HCl gas from the target area comprises supplying a second cleaning gas that is selected to react with HCl gas within the target area and to generate a compound having a lower toxicity than HCl gas.

6. The apparatus cleaning method of claim 5, wherein the removing HCl gas from the target area further comprises creating a vacuum in the target area before the supplying the second cleaning gas.

7. The apparatus cleaning method of claim 6, wherein the creating the vacuum in the target area comprises:
exhausting gas within the target area at a first flow rate; and
after the exhausting gas within the target area at the first flow rate, exhausting gas within the target area at a second flow rate greater than the first flow rate.

8. A substrate treatment apparatus comprising:
a substrate treatment chamber comprising a processing space configured to receive a substrate;
a processing gas supply configured to supply a processing gas into the processing space;
a first cleaning gas supply configured to supply, into the processing space, a first cleaning gas, wherein the first cleaning gas is selected to react with a compound including an Si—Cl bond and to generate HCl gas and a compound including an Si-bond that is more stable than the compound including the Si—Cl bond;
a second cleaning gas supply configured to supply, into the processing space, a second cleaning gas that is selected to react with the HCl gas to generate a compound having a lower toxicity than HCl gas;
memory storing instructions; and
a controller comprising one or more processors configured to individually or collectively execute the instructions,
wherein the instructions, when executed by the one or more processors individually or collectively, cause the substrate treatment apparatus to:
control the first cleaning gas supply to supply the first cleaning gas into the processing space, and
control the second cleaning gas supply to supply the second cleaning gas into the processing space.

9. The substrate treatment apparatus of claim 8, wherein the first cleaning gas is air having a humidity equal to or greater than a specific humidity.

10. The substrate treatment apparatus of claim 9, wherein the air is obtained outside the substrate treatment apparatus.

11. The substrate treatment apparatus of claim 8, further comprising:
a vacuum connected to the processing space,
wherein the instructions, when executed by the one or more processors individually or collectively, further cause the substrate treatment apparatus to:
control the vacuum to create a vacuum in the processing space after the first cleaning gas is supplied to the processing space and before the second cleaning gas is supplied to the processing space.

12. The substrate treatment apparatus of claim 11, wherein the vacuum comprises:
an exhaust pump configured to remove gas from within the processing space;
an exhaust line that is connected between the exhaust pump and the processing space; and
a valve configured to open and close the exhaust line,
wherein the exhaust line comprises:
a first exhaust line having a first inner diameter; and
a second exhaust line having a second inner diameter larger than the first inner diameter,
wherein the valve comprises:
a first valve configured to open and close the first exhaust line; and
a second valve configured to open and close the second exhaust line, and
wherein the instructions, when executed by the one or more processors individually or collectively, cause the substrate treatment apparatus to create a vacuum in the processing space by:
controlling the exhaust pump to operate,
controlling the first valve to open the first exhaust line for a specific time and to then close the first exhaust line, and
based on the first valve being closed, controlling the second valve to open the second exhaust line.

13. The substrate treatment apparatus of claim 8, further comprising:
a ventilation gas supply configured to supply ventilation gas into the processing space.

14. A substrate treatment apparatus comprising:
a substrate treatment chamber comprising a processing space configured to receive a substrate;
a substrate waiting chamber comprising a waiting space configured to hold the substrate, wherein the waiting space is adjacent to the processing space and is connected to the processing space by an opening;
a shutter configured to open and close the opening between the waiting space and the processing space; a substrate support configured to support the substrate and to move between the processing space and the waiting space through the opening;
a processing gas supply configured to supply a processing gas into the processing space;
a first cleaning gas supply configured to supply, into the processing space, a first cleaning gas, wherein the first cleaning gas is selected to react with a compound including an Si—Cl bond and to generate HCl gas and a compound with an Si-bonds that is more stable than the compound including the Si—Cl bond;
a second cleaning gas supply configured to supply, into the processing space, a second cleaning gas that is selected to react with the HCl gas to generate a compound having a lower toxicity than HCl gas;
memory storing instructions; and
a controller comprising one or more processors configured to individually or collectively execute the instructions,
wherein the instructions, when executed by the one or more processors individually or collectively, cause the substrate treatment apparatus to:
control the first cleaning gas supply to supply the first cleaning gas into the processing space, and
control the second cleaning gas supply to supply the second cleaning gas into the processing space.

15. The substrate treatment apparatus of claim 14, wherein the first cleaning gas is air having a humidity equal to or greater than a specific humidity.

16. The substrate treatment apparatus of claim 15, wherein the air is obtained outside the substrate treatment apparatus.

17. The substrate treatment apparatus of claim 14, further comprising:
a vacuum connected to the processing space,
wherein the instructions, when executed by the one or more processors individually or collectively, cause the substrate treatment apparatus to create a vacuum in the processing space by:
control the vacuum to create a vacuum in the processing space after the first cleaning gas is supplied to the processing space and before the second cleaning gas is supplied to the processing space.

18. The substrate treatment apparatus of claim 17, wherein the vacuum comprises:
an exhaust pump configured to remove gas from within the processing space;
an exhaust line that is connected between the exhaust pump and the processing space; and
a valve configured to open and close the exhaust line,
wherein the exhaust line comprises:
a first exhaust line having a first inner diameter; and
a second exhaust line having a second inner diameter larger than the first inner diameter,
wherein the valve comprises:
a first valve configured to open and close the first exhaust line; and
a second valve configured to open and close the second exhaust line, and
wherein the instructions, when executed by the one or more processors individually or collectively, cause the substrate treatment apparatus to create a vacuum in the processing space by:
controlling the exhaust pump to operate,
controlling the first valve to open the first exhaust line for a specific time and to then close the first exhaust line, and
based on the first valve being closed, controlling the second valve to open the second exhaust line.

19. The substrate treatment apparatus of claim 14, further comprising:
a partial pressure ratio control gas supply configured to supply, into the processing space, a partial pressure ratio control gas,
wherein the instructions, when executed by the one or more processors individually or collectively, cause the substrate treatment apparatus to:
based on the second cleaning gas is being supplied into the processing space, maintain a partial pressure of the second cleaning gas within the processing space within a set range by controlling the partial pressure ratio control gas supply to supply the partial pressure ratio control gas into the processing space.

20. The substrate treatment apparatus of claim 14, further comprising:
a ventilation gas supply configured to supply ventilation gas into the waiting space.
